(19) United States
(12) Patent Application Publication
(10) Pub. No.: US 2026/0223366 A1
(43) Pub. Date: Jul. 30, 2026

(54) CHARGE TRAPPING NOT OR (NOR) FLASH MEMORY ARCHITECTURES

(71) Applicant: Micron Technology, Inc., Boise, ID (US)

(72) Inventors: Agostino Pirovano, Milan (IT); Lorenzo Fratin, Buccinasco (IT); Fabio Pellizzer, Boise, ID (US); Innocenzo Tortorelli, Cernusco Sul Naviglio (IT)

(21) Appl. No.: 19/455,545

(22) Filed: Jan. 21, 2026

Related U.S. Application Data
(60) Provisional application No. 63/751,151, filed on Jan. 29, 2025.

(51) Int. Cl. H10B 43/20; G11C 16/04; H10B 43/10; H10B 43/35; H10B 43/40; H10B 43/50

(52) U.S. Cl. CPC H10B 43/20; G11C 16/0466; H10B 43/10; H10B 43/35; H10B 43/40; H10B 43/50

(57) ABSTRACT

Methods, systems, and devices for charge trapping not or (NOR) flash memory architectures are described. The devices described herein may implement a Fowler-Nordheim charge trapping NOR memory architecture. For example, a memory system may be manufactured that includes multiple NOR memory cells in a pier and pillar architecture. In such examples, the memory system may include multiple piers, where each pier may have a plurality of first cells at a first end of the pier and a plurality of second cells at a second end of the pier. Each pier may be positioned between a first pillar and a second pillar, where such pillars may be utilized to access the memory cells at each pier. In some examples, every other pillar may not include memory cells (e.g., may be a dielectric pillar), which may enable Fowler-Nordheim programming of the memory cells.

### CROSS REFERENCE

The present Application for Patent claims priority to U.S. Patent Application No. 63/751,151 by Pirovano et al., entitled “CHARGE TRAPPING NOT OR (NOR) FLASH MEMORY ARCHITECTURES,” filed January 29, 2025, which is assigned to the assignee hereof, and which is expressly incorporated by reference in its entirety herein

### TECHNICAL FIELD

The following relates to one or more systems for memory, including charge trapping not OR (NOR) flash memory architectures.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory system that supports charge trapping not OR (NOR) flash memory architectures in accordance with examples as disclosed herein.

FIG. 2 shows an example of an architecture that supports charge trapping NOR flash memory architectures in accordance with examples as disclosed herein.

FIGS. 3 and 4 show examples of various cross-sectional views that support charge trapping NOR flash memory architectures in accordance with examples as disclosed herein.

FIG. 5 shows a block diagram of a memory system that supports charge trapping NOR flash memory architectures in accordance with examples as disclosed herein.

FIG. 6 shows a flowchart illustrating a method or methods that support charge trapping NOR flash memory architectures in accordance with examples as disclosed herein.

### DETAILED DESCRIPTION

Some memory devices may be utilized for artificial intelligence (AI) applications. Such AI applications may involve increased read accesses within the memory device, where such read access may be associated with various latency metrics. Additionally, such AI applications may involve storing a relatively large quantity of data within the memory device. In such cases, however, it may be challenging to achieve read latencies and storage of large quantities of data for AI applications. Some memory systems may have fast read time (e.g., low read latencies), but those same memory devices may not have sufficient memory density (e.g., sufficient storage capacity) to store the increased quantity of data for AI applications, may not be cost effective, or both. For example, dynamic random access memory (DRAM) devices may be associated with read performances that satisfy the various latency metrics for AI applications, however, such DRAM devices may be associated with an increased cost and have a relatively lower memory density (e.g., reduced storage capacity) as compared to other devices. Some memory systems have large densities of memory cells, but the read latencies may not achieve what is needed for AI applications. For example, three dimensional (3D) NAND devices may have sufficient memory density for AI applications, but may be associated with increased read latency as compared to other systems, which may be insufficient for AI applications. Thus, memory solutions that provide for a higher memory density, while providing increased read performance at a lower cost may be desired. A charge trapping (CT) not OR (NOR) architecture may provide for a high density of memory cells, while providing increased read performance at a lower cost. However, CT NOR cells may use a different programming mechanism than some other memory systems, and may therefore be difficult to integrate into broader systems.

The techniques, methods, and devices described herein may provide for the use of a memory device that implements a Fowler-Nordheim (FN) CT NOR Flash memory architecture, which may provide for improved read performances and increased memory density, while maintaining a same programming mechanism as some other NAND systems. For example, a memory system may be manufactured that includes multiple NOR memory cells in a pier and pillar architecture. In such examples, the memory system may include multiple piers, where each pier may have a plurality of first cells at a first end of the pier and a plurality of second cells at a second end of the pier. Each pier may be positioned between a first pillar and a second pillar, where such pillars may be utilized to access the memory cells at each pier. In some examples, every other pier (e.g., one pier every two piers) may not include memory cells (e.g., may be a dielectric pillar), which may isolate the pillars and piers from other pillars and piers within the memory device, thereby enabling FN programming of the memory cells.

In addition to applicability in memory systems as described herein, techniques for charge trapping NOR memory architecture may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

Features of the disclosure are illustrated and described in the context of systems, devices, and circuits. Features of the disclosure are further illustrated and described in the context of architectures, cross-sectional views, and flowcharts.

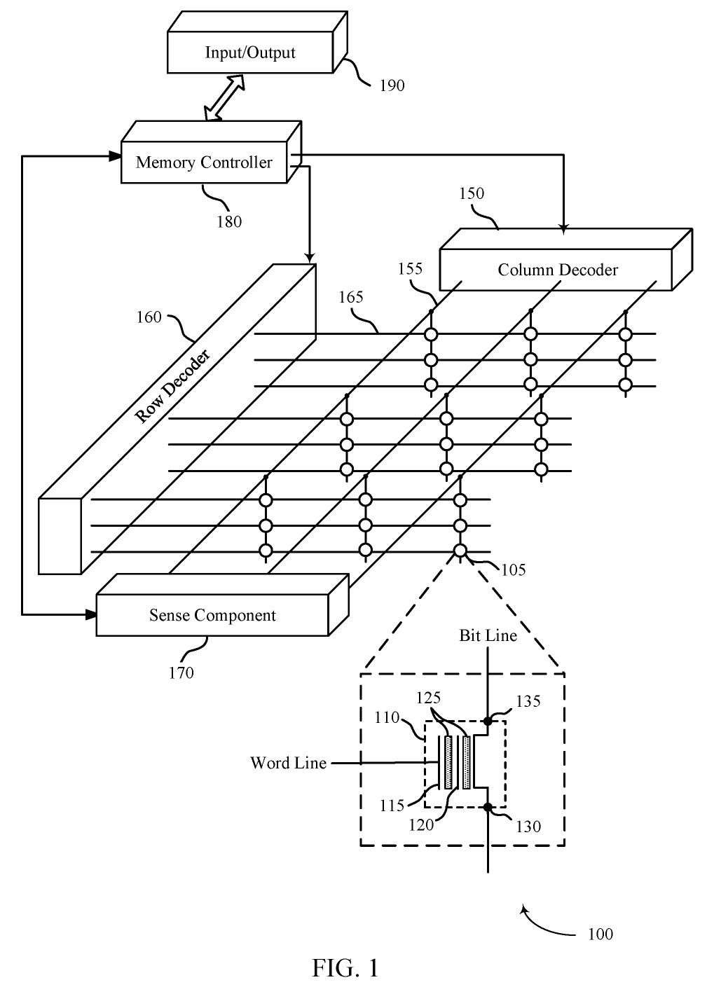

FIG. 1 shows an example of a memory device 100 that supports charge trapping NOR flash memory architectures in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

Developments in AI applications may lead to a memory solution that is capable of providing a high density memory array combined with improved read performance (e.g., reduced latency and increased bandwidth) at a low cost, without increased write performances. AI applications may involve increased read operations having reduced latency metrics as compared to other applications, while also involving storing an increased quantity of data within a memory device. Accordingly, read latencies associated with some other memory devices may not satisfy the latency metrics for AI applications. Alternatively, some memory devices may not have sufficient memory density (e.g., sufficient storage capacity) to store the increased quantity of data for AI applications, may not be cost effective, or both.

For example, DRAM memory devices may have a read performance that satisfies the latency and bandwidth metrics of such AI applications. However, such DRAM memory devices may be limited in memory density, not be cost effective, and involve an increased idle power to maintain the data. Alternatively, 3D NAND devices may provide for increased memory density (as compared to DRAM) and be cost effective. However, such 3D NAND devices may have increased latency due to the inherent string architecture utilized in 3D NAND systems, thereby being insufficient for AI applications. Some memory devices may utilize planar NOR memory cells, where such memory devices may have increased reading performances (e.g., similar to those of DRAM, but lacking in write performance and endurance) and provide an inherent advantage of non-volatility. Accordingly, a high-density NOR-like Flash memory may be utilized for AI applications (e.g., neural network executions).

According to the techniques described herein, the memory device 100 may include multiple charge trapping NOR Flash memory cells 105 in a pier and pillar architecture to increase the memory density (e.g., similar to 3D NAND three-bit-per-cell density) within the memory device 100 and improve read performance (e.g., have a relatively quicker random access speed, utilize decreased read voltages, have a higher bandwidth, among other advantages), while also reducing costs. For example, the memory device 100 may include multiple piers, where each pier may include multiple first memory cells 105 at a first end of the pier, and multiple second memory cells 105 at a second end of the pier.

To further increase the density (e.g., storage capacity) of the memory device 100, each memory cell 105 may be configured to store one or more bits of information. For example, each memory cell 105 may be configured as a single-level cell (SLC) to store a single bit of data or as a cell that stores two or more bits of data. For example, a memory cell 105 may be configured as a multi-level cell (MLC) that stores two bits of data, a triple-level cell (TLC) that stores three bits of data, a quad-level cell (QLC) that stores four bits of data, or a penta-level cell (PLC) that stores five bits of data. FIG. 1 illustrates a charge trapping NOR Flash memory cell 105 that includes a structure 110 that may be used to store two bits of data. The structure 110 may include a control gate 115 and a charge trapping structure 120, where the charge trapping structure 120 may, in some examples, be between two portions of dielectric material 125. The structure 110 also may include a first node 130 (e.g., a source or drain) and a second node 135 (e.g., a drain or source). One or more logic values may be stored in the memory cell 105 by storing (e.g., writing) a quantity of electrons (e.g., an amount of charge) on the charge trapping structure 120.

Piers and pillars may be positioned in a two-dimensional array, where each pier may be positioned between a first pillar and a second pillar and be coupled with the first and second pillar via respective conductive paths, where such pillars may be utilized to access the memory cells at each pier. Each respective first memory cell 105 and each respective second memory cell 105 of a pier may be connected to a corresponding word line 165, where such word lines 165 may be utilized to access one of the multiple first memory cells or one of the multiple second memory cells. Each row of pillars may be connected to a respective source/drain (S/D) line (not shown) via a first transistor (thin film transistor) and each first transistor along each column of pillars may be connected to a corresponding bit line 155 (e.g., digit line or gate line). Accordingly, the S/D lines (e.g., access lines) may be perpendicular to the bit lines 155 (e.g., gate lines). In some aspects, the pier and pillar architecture may include one or more piers that may not include memory cells. For example, every other pier (e.g., a pier positioned between every other pair of columns) may be comprised of an insulating material (e.g., a dielectric material) rather than a memory cell material.

To program a target memory cell 105, the column decoder 150 (e.g., gate line decoder) and a S/D decoder (not shown) may select the target memory cell 105 by biasing a drain pillar that corresponds to the memory cell (e.g., by activating a gate line and biasing a corresponding S/D line) with a first voltage, while the row decoder 160 may bias a word line 165 that corresponds to the memory cell 105 with a second voltage. The first voltage may be a relatively lower voltage (e.g., a negative voltage, such as -8 volts (V)) and the second voltage may be a relatively higher voltage (e.g., a positive voltage, such as +13 V). For example, the column decoder may activate a bit line 155, thereby selecting a column of pillars. Accordingly, the S/D decoder may select the S/D line corresponding to the drain pillar of the memory cell and may bias the drain pillar with the first voltage. Further, the row decoder 160 may bias the word line 165 that corresponds to the target memory cell 105 to the second voltage. In some examples, the S/D decoder may bias a source pillar corresponding to the memory cell with the first voltage or may set the voltage of the source pillar to a floating value. In some examples, the row decoder 160 may bias one or more other word lines of the array to a third voltage (e.g., a voltage between the first and second voltages, such as 0 V), one or more other gate lines may be deactivated, and the S/D decoder may bias one or more other S/D lines to a fourth voltage (e.g., a voltage between the second and third voltages, such as +2 V) or to a floating value.

A memory controller 180 may control the operation (e.g., read, write, re-write, refresh) of memory cells 105 through the various components (e.g., row decoder 160, column decoder 150, sense component 170, S/D decoder) and interface with an input/output function 190 (e.g., a host system). In some cases, one or more of a row decoder 160, a column decoder 150, a sense component 170, and a S/D decoder may be co-located with a memory controller 180. Such decoders may be referred to as thin-film transistor (TFT) decoders. A memory controller 180 may generate row and column address signals in order to activate a desired word line 165, bit line 155, and adjacent S/D lines. In some examples, a memory controller 180 may generate and control various voltages or currents used during the operation of memory device 100.

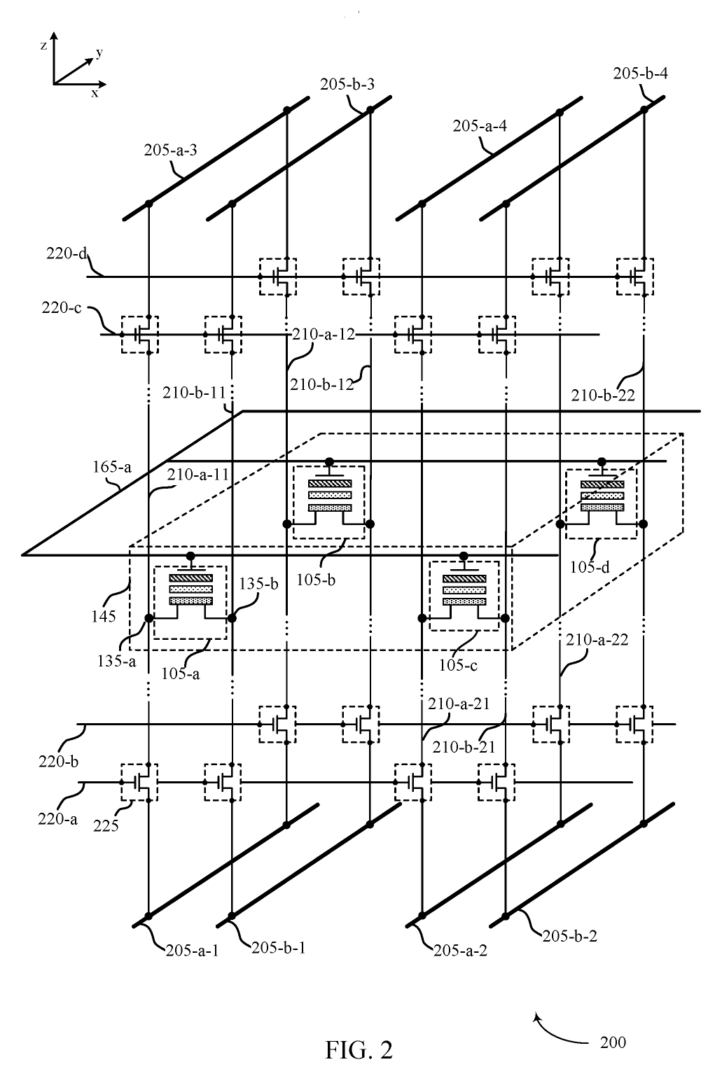

FIG. 2 shows an example of an architecture 200 that supports charge trapping NOR flash memory architectures in accordance with examples as disclosed herein. The architecture 200 may be an example of portions of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of an architecture 200 may be described with reference to an x-direction, a y-direction, and a z-direction of the illustrated coordinate system.

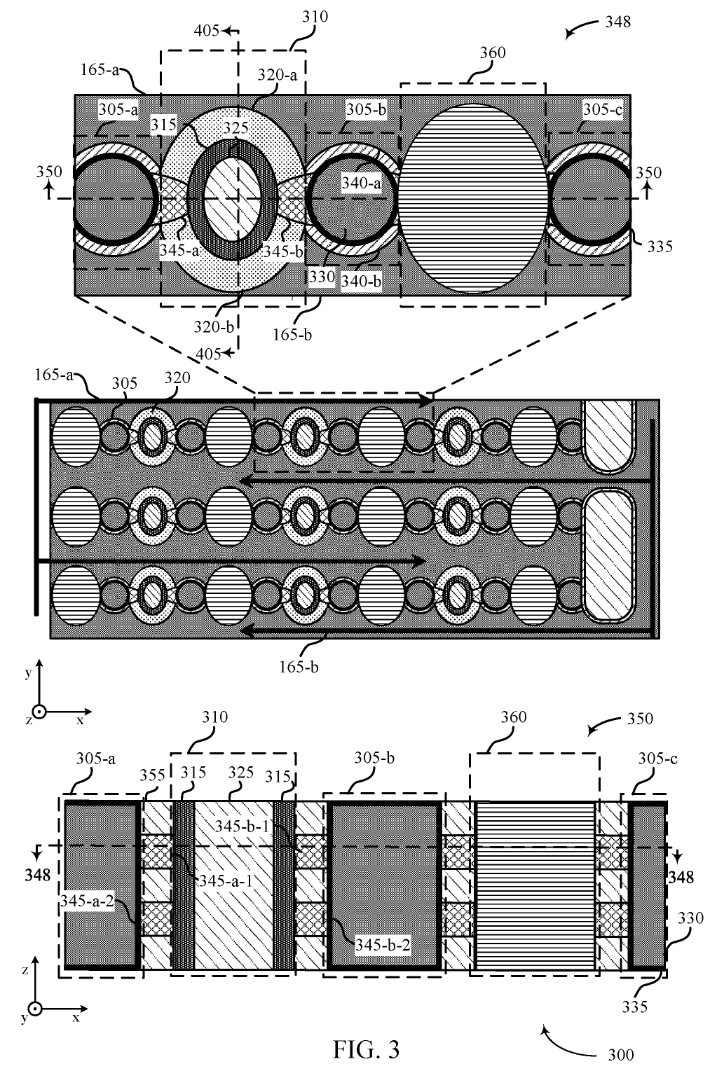

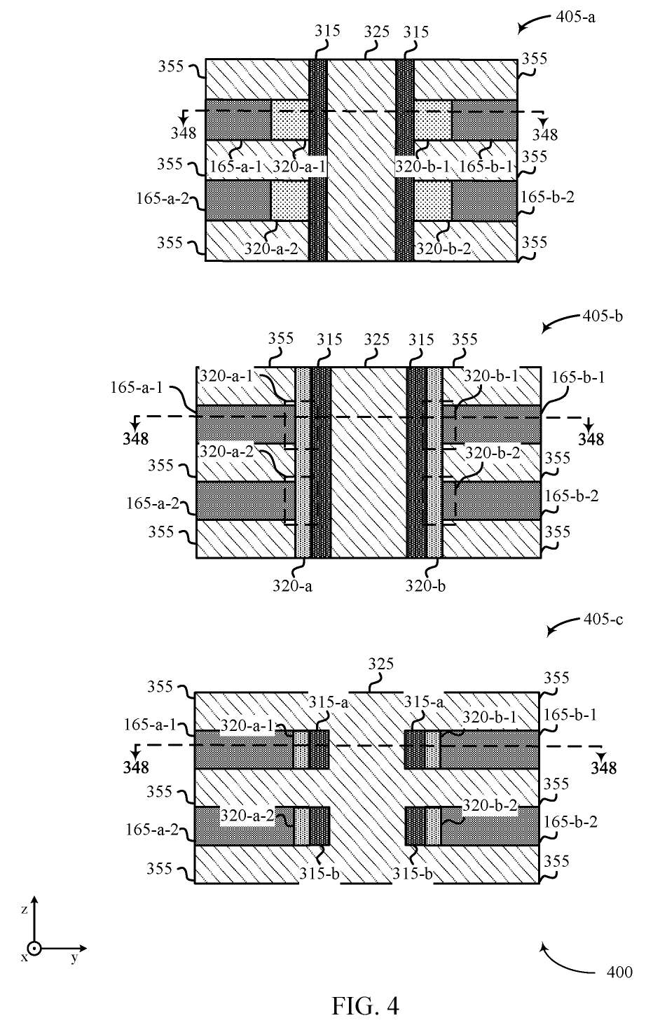

The architecture 200 illustrates a 3D array of memory cells 105 (e.g., transistors), which may be connected in a 3D NOR configuration. For example, memory cells 105 may be arranged in columns of piers along the z-direction, each of which may include one or more stacks of memory cells 105 along the z-direction (not shown). In some examples, each column may be associated with a channel (e.g., a semiconductor channel, a semiconductor pillar) along the z-direction. A memory device may include any quantity of one or more columns in accordance with examples as disclosed herein. In some implementations, each column may be associated with one or more piers including a first set of memory cells 105 at a first side of the column (e.g., along the y-direction) and a second set of memory cells 105 at a second side of the column opposite the first side (e.g., along the y-direction, not illustrated). Such columns may be further described herein with reference to FIGS. 3 and 4.

Each column of piers may be associated with and positioned between one or more pillars (e.g., a S/D pillar 210), including a respective S/D pillar 210-a (e.g., a drain pillar) and a respective S/D pillar 210-b (e.g., a source pillar), and each memory cell 105 along a column may be coupled with the same S/D pillar 210-a and the same S/D pillar 210-b. For example, a same S/D pillar 210-a may be coupled with a node 135-a (e.g., a drain node) of each memory cell 105 of a column, while a same S/D pillar 210-b may be coupled with a node 135-b (e.g., a source node) of each memory cell 105 of the column.

As illustrated, the node 135-a of the memory cell 105-a may be coupled with the S/D pillar 210-a-11 and the node 135-b of the memory cell 105-a may be coupled with the S/D pillar 210-b-11. In some examples, one or more adjacent pillars may not include a respective column of piers of memory cells. For example, every other column of piers between S/D pillars 210 may include skipped piers formed from another material, such as a dielectric material. Accordingly, cells on a same word line 165 may not share S/D pillars 210 and each pier may include two transistors (e.g., with one cell per transistor for SLC programming or multiple cells per transistor for MLC or TLC, which may result in a relatively higher density of memory cells and a relatively larger latency associated with read commands).

In some examples, the S/D pillar 210-a of one or more columns of piers (e.g., in a group along the y-direction) may be coupled with a same S/D selector 205-a (e.g., an access line, a multiplexing line, an S/D line). For example, the S/D pillar 210-a-11 coupled with memory cells 105-a of one column and the S/D pillar 210-a-12 coupled with memory cells 105-b of another column may both be coupled (e.g., via a respective transistor 225, TFT transistor) with a S/D selector 205-a-1. Likewise, the S/D pillar 210-a-21 coupled with memory cells 105-c of one column and the S/D pillar 210-a-22 coupled with memory cells 105-d of another column may both be coupled with a S/D selector 205-a-2. Further, the S/D pillar 210-b-11 coupled with memory cells 105-a of one column and the S/D pillar 210-b-12 coupled with memory cells 105-b of another column may both be coupled (e.g., via a respective transistor 225) with a S/D selector 205-b-1. Likewise, the S/D pillar 210-b-21 coupled with memory cells 105-c of one column and the S/D pillar 210-b-22 coupled with memory cells 105-d of another column may both be coupled with a S/D selector 205-b-2.

Additionally, the S/D pillars 210-a and 210-b of one or more columns may be coupled via a gate line 220 (e.g., activation line, access line) along the x-direction. For example, the S/D pillars 210-a-11, 210-b-11, 210-a-21, and 210-b-21 may be coupled, via a respective transistor 225, via the gate line 220-a. Similarly, the S/D pillars 210-a-12, 210-b-12, 210-a-22, and 210-b-22 may be coupled with the gate line 220-b, where such gate lines 220 may be activated to facilitate access to one or more memory cells 105.

In some aspects, such S/D selectors 205 and gate lines 220 may be positioned at both of a first end (e.g., bottom) and a second end (e.g., top) of the architecture 200 along the z-direction, (e.g., in a split top-bottom S/D pillar architecture with a TFT decoder), where both sets of S/D selectors 205 and gate lines 220 may be utilized to reduce programming disturbances of one or more unselected memory cells 105 of the array.

For example, the S/D pillar 210-a-11 coupled with memory cells 105-a of one column and the S/D pillar 210-a-12 coupled with memory cells 105-b of another column may both be coupled (e.g., via a respective transistor 225) with a S/D selector 205-a-3. Likewise, the S/D pillar 210-a-21 coupled with memory cells 105-c of one column and the S/D pillar 210-a-22 coupled with memory cells 105-d of another column may both be coupled with a S/D selector 205-a-4. Further, the S/D pillar 210-b-11 coupled with memory cells 105-a of one column and the S/D pillar 210-b-12 coupled with memory cells 105-b of another column may both be coupled (e.g., via a respective transistor 225) with a S/D selector 205-b-3. Likewise, the S/D pillar 210-b-21 coupled with memory cells 105-c of one column and the S/D pillar 210-b-22 coupled with memory cells 105-d of another column may both be coupled with a S/D selector 205-b-4.

Additionally, the S/D pillars 210-a and 210-b of one or more columns, along the x-direction, may be coupled via a gate line 220 (e.g., activation line, access line) at a top of the architecture 200. For example, the S/D pillars 210-a-11, 210-b-11, 210-a-21, and 210-b-21 may be coupled, via a respective transistor 225, via the gate line 220-c. Similarly, the S/D pillars 210-a-12, 210-b-12, 210-a-22, and 210-b-22 may be coupled with the gate line 220-d, where such gate lines 220 may be activated to facilitate access to one or more memory cells 105.

In the example of architecture 200, the array of memory cells 105 may also be divided into a set of planes 145 arranged along the z-direction, including a plane 145 associated with memory cells 105-a-2 through 105-f-2, and so on. In some examples, all memory cells 105 of a plane may be activated by a same word line 165. In some other examples, subsets of memory cells 105 of a given plane 145 may be activated by a respective one of multiple word lines 165 associated with the given plane 145. For example, a plane 145 may be associated with word lines 165 configured in accordance with a comb structure (e.g., even and odd word lines 165). Such combed word lines 165 may be formed such that portions of the word line 165 (e.g., conductor portions, projections, tines) extend along the x-direction through gaps (e.g., alternating gaps) between columns.

For example, the architecture 200 may include two word lines 165 per plane 145(e.g., according to odd word lines 165-a, with projections along the positive x-direction, and even word lines (not shown), with projections along the negative x-direction), where such word lines 165 of the same plane 145 may be described as being interleaved (e.g., with portions of an odd word line 165- projecting along the x-direction between portions of an even word line 165, and vice versa).

In some examples, an even word line 165-b may be associated with a first memory cell 105 on a first side (e.g., along the y-direction) of a given column and an odd word line 165-a (e.g., of the same plane 145) may be associated with a second memory cell 105 on a second side (e.g., along the y-direction, opposite the first memory cell 105) of the given column. Thus, in some examples, memory cells 105 of a given plane 145 may be addressed (e.g., selected, activated, multiplexed) in accordance with an even word line 165 or an odd word line 165. Such combed word lines 165 may be further described and illustrated with respect to FIG. 3.

In some examples, to program the memory cell 105-a, the architecture 200 may utilize a single set of S/D selectors 205-a and 205-b and a single gate line 220. As an illustrative example, to program the memory cell 105-a, one or more first decoders (e.g., the row decoder 160) may bias the word line 165-a to a first voltage (e.g., 13 V) and bias the other word lines 165 (e.g., other odd word lines 165 and each even word line 165) of the architecture 200 to a ground voltage (e.g., 0 V). Accordingly, one or more second decoders (e.g., gate line decoders) may activate the gate line 220-a by biasing the gate line 220-a to a second voltage.

Further, one or mor third decoders (e.g., S/D decoders) may bias the S/D selector 205-a-1 with a third voltage (e.g., -8 V). Accordingly, because the gate line 220-a is activated and the S/D selector 205-a-1 is biased to the third voltage, the S/D pillar 210-a-11 may also be biased with the third voltage. Similarly, the one or more third decoders may bias the S/D selector 205-b-1 to the third voltage (e.g., -8 V) or to a float state, such that the S/D pillar 210-b-11 is biased to the third voltage or the float state. The one or more third decoders may also bias all other S/D selectors 205 to a fourth voltage (e.g., 2 V) or to the float state. For example, the one or more third decoders may bias the S/D selectors 205-a-2 and 205-b-2 to the fourth voltage or the float state.

In this way, the memory cell 105-a may have a fifth voltage (e.g., 21 V) applied across the gate (e.g., ML-CT gate) of the memory cell 105-a, thereby programming the memory cell 105-a via the FN mechanism. For example, as part of the FN mechanism, the fifth voltage may generate an electric field across the gate of the memory cell 105-a, which may cause electrons to tunnel into the charge trapping structure 120 of the memory cell 105-a, thereby altering the state of the memory cell 105-a.

In such examples, a sixth voltage (e.g., 11 V or 13 V) may be applied to the gates of the unselected memory cells 105-b, 105-c and 105-d, which may be within the same plane 145 and share the same word line 165-a, where the sixth voltage may be based on whether the unselected S/D selectors 205 are biased or floating. Further, the third voltage (e.g., - 8 V) may be applied to the gates of the unselected memory cells 105 in a same column as the memory cell 105-a (e.g., in different tiers). Further, all other unselected memory cells 105 (e.g., those not in a same column or plane 145 as the memory cell 105-a) may have no voltage drop across the respective gates and may have the channel boosted to the ground voltage (e.g., 0 V).

In some other examples, to program the memory cell 105-a, the architecture 200 may utilize both sets of S/D selectors 205-a and 205-b and both gate lines 220. As an illustrative example, to program the memory cell 105-a, one or more first decoders (e.g., the row decoder 160) may bias the word line 165-a to a first voltage (e.g., 13 V) and bias the other word lines 165 (e.g., other odd word lines 165 and each even word line 165) of the architecture 200 to a ground voltage (e.g., 0 V).

Accordingly, one or more second decoders (e.g., gate line decoders) may activate the gate line 220-a by biasing the gate line 220-a to a second voltage. Further, one or mor third decoders (e.g., S/D decoders) may bias the S/D selector 205-a-1 with a third voltage (e.g., -8 V). Accordingly, because the gate line 220-a is activated and the S/D selector 205-a-1 is biased to the third voltage, the S/D pillar 210-a-11 may also be biased with the third voltage. Similarly, the one or more third decoders may bias the S/D selector 205-b-1 to the third voltage (e.g., -8 V) or to a float state, such that the S/D pillar 210-b-11 is biased to the third voltage or the float state. The one or more third decoders may also bias all other S/D selectors 205 to a fourth voltage (e.g., 2 V) or to the float state. For example, the one or more third decoders may bias the S/D selectors 205-a-2 and 205-b-2 to the fourth voltage or the float state.

Similarly, the one or more second decoders may deactivate the gate line 220-c, while activating the gate line 220-d (e.g., activating all other gate lines 220 above the architecture 200). Further the one or more third decoders may bias the S/D selectors 205-a-3, 205-b-3, 205-a-4, and 205-b-4 to the fourth voltage or the float state. In this way, the memory cell 105-a may have the fifth voltage (e.g., 21 V) applied across the gate (e.g., ML-CT gate) of the memory cell 105-a, thereby programming the memory cell 105-a via the FN mechanism, as described above.

In such examples, a sixth voltage (e.g., 11 V or 13 V) may be applied to the gates of the unselected memory cells 105-b, 105-c and 105-d, which may be within the same plane 145 and share the same word line 165-a, where the sixth voltage may be based on whether the unselected S/D selectors 205 are biased or floating. Further, the third voltage (e.g., - 8 V) may be applied to the gates of the unselected memory cells 105 in a same column as the memory cell 105-a (e.g., in different tiers). Further, by deactivating the gate line 220-c, all other unselected memory cells 105 (e.g., those not in a same column or plane 145 as the memory cell 105-a) may have no voltage drop or a controlled seventh voltage (e.g., -2 V) applied across the respective gates and may have the channel boosted to the ground voltage (e.g., 0 V), which may further reduce programming disturbances across such memory cells.

FIG. 3 shows an example of a various cross-sectional views of a memory device 300 that supports charge trapping NOR flash memory architectures in accordance with examples as disclosed herein. Aspects of the memory device 300 may implement, or be implemented by, aspects of the memory device 100 or the architecture 200. For example, the memory device 300 may include one or more charge trapping NOR flash memory cells 105 configured in a pier and pillar architecture, as described herein with reference to FIG. 1. The memory device 300 may provide for increased memory density and improved read performances. In some cases, the memory cells may be examples of Fowler-Nordheim charge trapping (e.g., FNCT) NOR memory cells.

With respect to the top view 348, the memory device 300 may include multiple active piers 310 formed into a stack of materials that alternates between word lines 165 and oxide layers 355, where each active pier 310 may be positioned between a respective pair of pillars 305 (e.g., forming a comb-like structure in the word lines 165). For example, an active pier 310 may be positioned between a pillar 305-a (e.g., first pillar) and a pillar 305-b (e.g., a second pillar). Each active pier 310 may include memory cells 320-a (e.g., charge trapping NOR Flash memory cells 105) at a first end of the active pier 310 (e.g., in the y-direction), where the memory cells 320-a extend along the z-direction of the memory device 300 and each memory cell 320-a may be coupled with a respective word line 165 (e.g., an even or odd word line). Similarly, each active pier 310 may include memory cells 320-b at a second end of the active pier 310 (e.g., in the y-direction), where the memory cells 320-a extend along the z-direction of the memory device 300 and each memory cell 320-b may be coupled with a respective word line 165 (e.g., an even or odd word line based on the position of the active pier 310 within the memory device 300).

Each active pier 310 may further include a conductive layer 315 (e.g., p-type poly-silicon) that is coupled with an inner surface of each memory cell 320-a of multiple memory cells 320-a and is coupled with an inner surface of each memory cell 320-b of multiple memory cells 320-b. Additionally, each active pier 310 may include a core dielectric material 325 (e.g., a multi-stack dielectric composed by silicon oxide, silicon nitride, silicon oxide layers, or a combination thereof) that is coupled with an inner surface of the conductive layer 315. Various examples of a cross sectional view 405 of the active piers 310 are illustrated will reference to FIG. 4.

As described herein, each memory cell 320 may be formed using a charge trapping material (e.g., charge trapping multi-layer material), where, in some examples, the charge trapping material may be recessed (e.g., confined or positioned) at each word line deck (e.g., at a same even and odd word line 165), such that each memory cell 320-a may correspond to a respective word line 165-a and each memory cell 320-b may correspond to a respective word line 165-b. Alternatively, in some examples, the charge trapping material may be continuous along the z-direction of the memory device 300. Similarly, in some examples, the conductive layer 315 may be continuous (e.g., in the z-direction) through the memory device 300. For example, as illustrated in the cross-sectional view 350, the conductive layer 315 may be continuous (in the z-direction) through the memory device 300. Alternatively, the conductive layer 315 may be recessed within each word line deck.

In some aspects, with respect to the top view 348, the memory device 300 may further include inactive piers 360 (e.g., skipped piers) formed into the stack of materials, where each inactive pier 360 may be positioned between a second respective pair of pillars 305. For example, an inactive pier 360 may be positioned between the pillar 305-b (e.g., the second pillar) and a pillar 305-c (e.g., a third pillar). Each inactive pier 360 may be formed from an insulating material (e.g., a dielectric material). Accordingly, each inactive pier 360 may isolate the pillar 305-b from the pillar 305-c.

Each pillar 305 may include a metal material 330, which may be coupled with an inner surface of a barrier material 335 (e.g., titanium silicon (TiSi) or tungsten nitride (WN)). To avoid shorts between the metal material 330 of the pillars 305 and the word lines 165, the memory device 300 may include a dielectric material 340-a (e.g., aluminum oxide (AlOx), hafnium oxide (HfOx), silicon oxycarbide (SiOC), silicon carbonitride (SiCN), or a combination thereof) at a first end (in the y-direction) of the pillar 305 that separates the first end of the pillar 305 from the word line 165-a. Similarly, the memory device may include a dielectric material 340-b at a second end of the pillar 305 that separates the pillar 305 from the word line 165-b. In such examples, respective portions of the dielectric material 340-a and 340-b may be recessed at each word line 165. Alternatively, the dielectric materials 340 may extend continuously through the memory device 300 in the z-direction.

Each pillar 305 may be coupled with the memory cells 320 and the conductive layer 315 of the active piers 310 via respective conductive paths 345 (e.g., formed from n-type polysilicon). For example, with respect to the cross-sectional view 350, the pillar 305-a may be coupled with each of the memory cells 320-a, each of the memory cells 320-b, and the conductive layer 315 via a respective conductive path 345-a, while the pillar 305-b may be coupled with each of the memory cells 320-a, each of the memory cells 320-b, and the conductive layer 315 via a respective conductive path 345-b. As described herein, a location of each respective conductive paths 345 may correspond to a respective word line 165 (e.g., a respective word line deck). For example, the locations of the conductive paths 345-a-1 and 345-b-1 may correspond to a first word line deck (e.g., first set of even and odd word lines 165), while the locations of the conductive paths 345-a-2 and 345-b-2 may correspond to a second word line deck (e.g., a second set of even and odd word lines 165).

The active piers 310 and the pillars 305 may be formed in a two-dimensional array. Accordingly, each column of pillars 305 may be coupled with a respective gate line (e.g., bit line 155), while each row pillars 305 may be coupled with a respective S/D line via a first transistor. The pillars 305 may be configured as source or drains to access the memory cells 320 of the active piers 310.

As an illustrative example, to program (e.g., write) a first bit of a memory cell 320-a, a gate line decoder (e.g., column decoder) may bias (e.g., turn on) the gate line coupled with the pillars 305-a and 305-b, while the gate line decoder deactivates (e.g., turns off) the other gate lines. As such, the S/D decoder may configure the pillar 305-a as a drain by biasing the S/D line coupled with the pillar 305-a to a first voltage (e.g., a negative voltage, such as -8 V) and may configure the pillar 305-b as a drain by biasing the S/D line coupled with the pillar 305-b to the first voltage or by setting the S/D line coupled with the pillar 305-b to a float state.

A row decoder may bias the word line 165 coupled with the memory cell 320-a with a second voltage (e.g., greater than the first voltage, such as a large positive voltage +13 V), and may set remaining word lines 165 to a third voltage between the first and second voltages (e.g., a ground voltage 0 V). The S/D decoder may set the S/D lines coupled with the other pillars 305 to a float state, or may bias the S/D lines coupled with the other pillars 305 to a fourth voltage between the second voltage and the third voltage (e.g., a small positive voltage, such as +2 V).

Accordingly, the memory cell 320-a (e.g., the target memory cell) may have a relatively larger bias across a multi-level charge trapping (ML-CT) gate (e.g., a bias of +21 V), which may program a value to the memory cell 320-a (e.g., via an FN mechanism). The memory cell 320-b (e.g., an unselected cell on a same pier 310 and coupled with a same word line 165 and gate line as the memory cell 320-a) may have a relatively smaller bias (e.g., +11 V or +13 V), and may therefore not be programmed. One or more other memory cells 320 (e.g., unselected cells on a different pier 310 but coupled with a same word line 165 and gate line as the memory cell 320-a) may have a relatively smaller bias (e.g., -8 V) across the ML-CT gate, and may therefore not be programmed. One or more other memory cells 320 (e.g., unselected cells on a different pier 310 and coupled with a different word line 165 or gate line as the memory cell 320-a) may have a relatively smaller bias (e.g., 0 V, no voltage drop across the ML-CT gate), and may therefore not be programmed.

In some aspects, if the memory device 300 includes an array of S/D lines (e.g., and gate lines) on multiple sides of the array of word lines 165, to program the memory cell 320-a, the row decoder may bias the word line 165 coupled with the memory cell 320-a with a second voltage (e.g., greater than the first voltage, such as a large positive voltage +13 V), and may set remaining word lines 165 to a third voltage between the first and second voltages (e.g., a ground voltage 0 V).

A gate line decoder (e.g., column decoder) may bias (e.g., turn on) a gate line coupled with the pillars 305-a and 305-b on a first side of the memory device 300 (e.g., on the bottom of the pillars 305), while the gate line decoder deactivates (e.g., turns off) the other gate lines on the first side of the memory device 300. As such, the S/D decoder may configure the pillar 305-a as a drain by biasing an S/D line coupled with the pillar 305-a on the first side to a first voltage (e.g., a negative voltage, such as -8 V) and may configure the pillar 305-b as a drain by biasing the S/D line coupled with the pillar 305-b on the first side to the first voltage or by setting the S/D line coupled with the pillar 305-b to a float state. The S/D decoder may set the S/D lines coupled with the other pillars 305 on the first side to a float state, or may bias the S/D lines coupled with the other pillars 305 to a fourth voltage between the second voltage and the third voltage (e.g., a small positive voltage, such as +2 V).

The gate line decoder may deactivate a gate line coupled with the pillars 305-a and 305-b on a second side of the memory device 300 (e.g., on the top of the pillars 305), and may bias (e.g., turn on) the other gate lines on the second side of the memory device 300. The S/D decoder may set the S/D lines coupled with the other pillars 305 on the second side to the float state, or may bias the S/D lines coupled with the other pillars 305 to the fourth voltage between the second voltage and the third voltage (e.g., +2 V).

Accordingly, the memory cell 320-a (e.g., the target memory cell) may have a relatively larger bias across a ML-CT gate (e.g., a bias of +21 V), which may program a value to the memory cell 320-a (e.g., via an FN mechanism). The memory cell 320-b (e.g., an unselected cell on a same pier 310 and coupled with a same word line 165 and gate line as the memory cell 320-a) may have a relatively smaller bias (e.g., +11 V or +13 V), and may therefore not be programmed. One or more other memory cells 320 (e.g., unselected cells on a different pier 310 but coupled with a same word line 165 and gate line as the memory cell 320-a) may have a relatively smaller bias (e.g., -8 V) across the ML-CT gate, and may therefore not be programmed. One or more other memory cells 320 (e.g., unselected cells on a different pier 310 and coupled with a different word line 165 or gate line as the memory cell 320-a) may have a relatively smaller bias (e.g., +2 V or a grounded state such as 0 V), and may therefore not be programmed. Such techniques may inhibit the unselected cells (e.g., by controlling a voltage across the unselected memory cells 320, such as the unselected cells on a different pier 310 and coupled with a different word line 165 or gate line as the memory cell 320-a), which may reduce a risk or program disturbance as compared to uncontrolled voltages across the unselected cells.

In some aspects, to read the value of a memory cell 320, a memory controller may perform a 2-terminal S/D read (e.g., thorough a horizontal channel), which may mitigate performance degradation related to string resistance and may increase a random/sequential read performance as compared to other NAND devices.

The memory device 300 may be configured to support code storage and execution for AI inference and applications. For example, the memory device 300 may include a relatively higher storage capacity (e.g., memory density) as compared to other memory systems (e.g., DRAM or 3D NAND systems), may include improved read performance (e.g., increased read speed, lower active power during read operations, lower cost per bit, lower standby power) as compared to other memory systems, may enable execute in place applications, among other benefits. Such characteristics may provide improved performance for systems operating AI applications.

FIG. 4 shows an example of various cross-sectional views 400 of the memory device 300 that support charge trapping NOR flash memory architectures in accordance with examples as disclosed herein. As described herein with respect to FIG. 3, in some examples, the conductive layer 315 may extend continuously through the memory device 300 in the z-direction.

For example, with respect to the cross-sectional view 405-a, the conductive layer 315 of each active pier 310 may extend continuously through the stack of oxide layers 355 and word lines 165 of the memory device 300. Additionally, as described herein with respect to FIG. 3, each memory cell 320 may be positioned (e.g., recessed or confined) to a respective word line deck (e.g., set of even and odd word lines 165). With respect to the cross section view 405-a, each memory cell 320 may be positioned between respective oxide layers 355 and be coupled with a respective word line 165. For example, the memory cell 320-a-1 may be positioned between two oxide layers 355 and be coupled with the word line 165-a-1, while the memory cell 320-a-2 may be positioned between two oxide layers 355 and be coupled with the word line 165-a-2. Similarly, the memory cell 320-b-1 may be positioned between two oxide layers 355 and be coupled with the word line 165-b-1, while the memory cell 320-b-2 may be positioned between two oxide layers 355 and be coupled with the word line 165-b-2.

Additionally, or alternatively, with respect to the cross-sectional view 405-b, the charge trapping material that forms the memory cells 320-a may be continuous along the z-direction of the memory device 300. Similarly, the charge trapping material that forms the memory cells 320-b may be continuous along the z-direction of the memory device 300. In such examples, although the charge trapping material may be continuous throughout the memory device, the memory cells 320 (e.g., points of charge trapping material that store the data) may be formed at the intersection of the word lines 165 and the charge trapping material.

For example, the memory cell 320-a-1 may be formed at the intersection of the word line 165-a-1 and the charge trapping material that forms the memory cells 320-a, while the memory cell 320-a-2may be formed at the intersection of the word line 165-a-2 and the charge trapping material that forms the memory cells 320-a. Similarly, the memory cell 320-b-1 may be formed at the intersection of the word line 165-b-1 and the charge trapping material that forms the memory cells 320-b, while the memory cell 320-b-2 may be formed at the intersection of the word line 165-b-2 and the charge trapping material that forms the memory cells 320-b.

Additionally, or alternatively, with respect to the cross sectional view 405-c, the conductive layer 315-a (e.g., a first conductive layer) may be positioned between two oxide layers 355 and be coupled with the memory cells 320-a-1 and 320-b-1, thereby being recessed at a first word line deck (e.g., the word line deck or layer corresponding to word lines 165-a-1 and 165-b-1). Similarly, the conductive layer 315-b (e.g., a second conductive layer) may be positioned between two oxide layers 355 and be coupled with the memory cells 320-a-2 and 320-b-2, thereby being recessed at a second word line deck (e.g., the word line deck or layer corresponding to the word lines 165-a-2 and 165-b-2).

Additionally, the conductive layers 315 may be coupled with a respective conductive path 345, as illustrated with reference to FIG. 3. For example, due to each conductive layer 315 being recessed at a respective word line deck, the conductive layer 315-a may be coupled with the conductive paths 345-a-1 and 345-b-1, while the conductive layer 315-b may be coupled with the conductive paths 345-a-2 and 345-b-2. The structure illustrated in the memory device 300 may enable the memory cells 320 to be fully confined (e.g., recessed or positioned) at each word line deck.

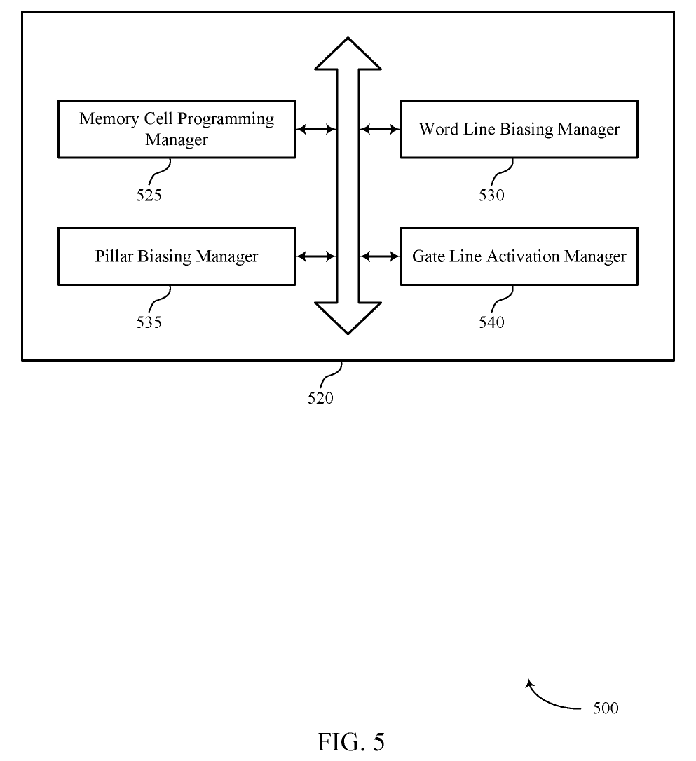

FIG. 5 shows a block diagram 500 of a memory system 520 that supports charge trapping NOR flash memory architectures in accordance with examples as disclosed herein. The memory system 520 may be an example of aspects of a memory system as described with reference to FIGs.

The memory system 520, or various components thereof, may be an example of means for performing various aspects of charge trapping NOR flash memory architectures as described herein. For example, the memory system 520 may include a memory cell programming manager 525, a word line biasing manager 530, a pillar biasing manager 535, a gate line activation manager 540, or any combination thereof. Each of these components, or components of subcomponents thereof (e.g., one or more processors, one or more memories), may communicate, directly or indirectly, with one another (e.g., via one or more buses).

The memory system 520 may support operating a memory device in accordance with examples as disclosed herein. The memory cell programming manager 525 may be configured as or otherwise support a means for programming a memory cell of a memory array. To perform the programming, the word line biasing manager 530 may be configured as or otherwise support a means for biasing a first word line of a plurality of word lines with a first voltage, where the first word line is coupled with the memory cell. In some examples, the word line biasing manager 530 may be configured as or otherwise support a means for biasing one or more second word lines of the plurality of word lines with a second voltage that is less than the first voltage. The pillar biasing manager 535 may be configured as or otherwise support a means for biasing a first pillar of a plurality of pillars of the memory array with a third voltage that is less than the second voltage, the first pillar being coupled with the memory cell, where a charge is stored in the memory cell in accordance with biasing the first word line with the first voltage, biasing the one or more second word lines with the second voltage, and biasing the first pillar with the third voltage.

In some examples, to support biasing the first pillar with the third voltage, the pillar biasing manager 535 may be configured as or otherwise support a means for biasing a first access line of a plurality of first access lines with the third voltage, the first pillar coupled with the first access line.

In some examples, the pillar biasing manager 535 may be configured as or otherwise support a means for biasing one or more additional access lines of the plurality of first access lines with a fourth voltage, where the fourth voltage is less than the first voltage and greater than the second voltage.

In some examples, to support programming the memory cell, the pillar biasing manager 535 may be configured as or otherwise support a means for biasing a second pillar of the plurality of pillars with the third voltage, the second pillar being coupled with the memory cell.

In some examples, to support biasing the second pillar with the third voltage, the pillar biasing manager 535 may be configured as or otherwise support a means for biasing a second access line of the plurality of first access lines with the third voltage, the second pillar coupled with the second access line.

In some examples, to support programming the memory cell, the gate line activation manager 540 may be configured as or otherwise support a means for activating a first gate line of a plurality of first gate lines located at a first end of the first pillar, where the first gate line is coupled with the first pillar, and where biasing the first pillar and the second pillar of the plurality of pillars is in accordance with activating the first gate line.

In some examples, the gate line activation manager 540 may be configured as or otherwise support a means for deactivating one or more other gate lines of the plurality of first gate lines in accordance with activating the first gate line of the plurality of first gate lines.

In some examples, to support programming the memory cell, the gate line activation manager 540 may be configured as or otherwise support a means for deactivating a second gate line of a plurality of second gate lines located at a second end of the first pillar opposite the first end, where the second gate line is coupled with the first pillar and the second pillar. In some examples, to support programming the memory cell, the gate line activation manager 540 may be configured as or otherwise support a means for activating one or more other gate lines of the plurality of second gate lines in accordance with deactivating the second gate line of the plurality of second gate lines.

In some examples, the pillar biasing manager 535 may be configured as or otherwise support a means for biasing one or more access lines of a plurality of second access lines with a fourth voltage in accordance with activating the one or more other gate lines of the plurality of second gate lines, where the fourth voltage is less than the first voltage and greater than the second voltage, and where the one or more access lines of the plurality of second access lines are coupled with the second gate line.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

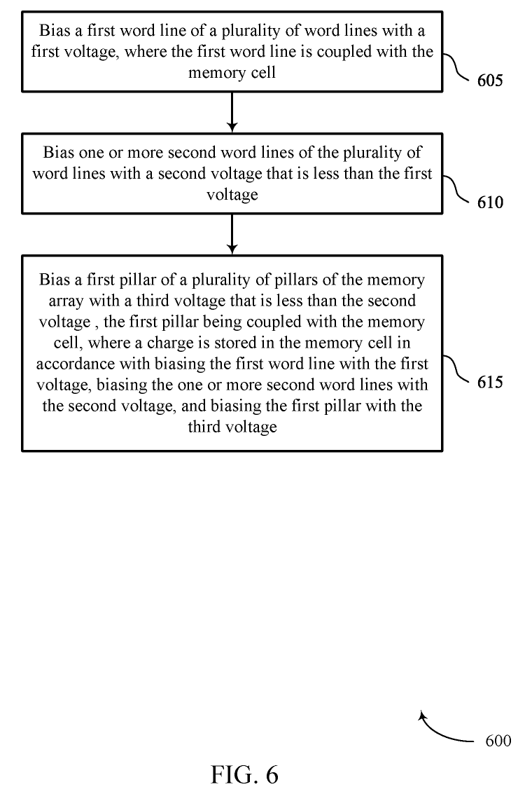

FIG. 6 shows a flowchart illustrating a method 600 that supports charge trapping NOR flash memory architectures in accordance with examples as disclosed herein. The operations of method 600 may be implemented by a memory system or its components as described herein. For example, the operations of method 600 may be performed by a memory system as described with reference to FIGs.

In some examples, a memory system may execute a set of instructions to control the functional elements of the device to perform the described functions. Additionally, or alternatively, the memory system may perform aspects of the described functions using special-purpose hardware. The method 600 may include programming a memory cell of a memory array. In some examples, aspects of the method 600 may be performed by a memory cell programming manager 525 as described with reference to FIG. 5.

At 605, the method may include biasing a first word line of a plurality of word lines with a first voltage, where the first word line is coupled with the memory cell. In some examples, aspects of the operations of 605 may be performed by a word line biasing manager 530 as described with reference to FIG. 5.

At 610, the method may include biasing one or more second word lines of the plurality of word lines with a second voltage that is less than the first voltage. In some examples, aspects of the operations of 610 may be performed by a word line biasing manager 530 as described with reference to FIG. 5.

At 615, the method may include biasing a first pillar of a plurality of pillars of the memory array with a third voltage that is less than the second voltage, the first pillar being coupled with the memory cell, where a charge is stored in the memory cell in accordance with biasing the first word line with the first voltage, biasing the one or more second word lines with the second voltage, and biasing the first pillar with the third voltage. In some examples, aspects of the operations of 615 may be performed by a pillar biasing manager 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for programming a memory cell of a memory array, where the programming includes; biasing a first word line of a plurality of word lines with a first voltage, where the first word line is coupled with the memory cell; biasing one or more second word lines of the plurality of word lines with a second voltage that is less than the first voltage; and biasing a first pillar of a plurality of pillars of the memory array with a third voltage that is less than the second voltage, the first pillar being coupled with the memory cell, where a charge is stored in the memory cell in accordance with biasing the first word line with the first voltage, biasing the one or more second word lines with the second voltage, and biasing the first pillar with the third voltage.

Aspect 2: The method, apparatus, or non-transitory computer-readable medium of aspect 1, where biasing the first pillar with the third voltage includes operations, features, circuitry, logic, means, or instructions, or any combination thereof for biasing a first access line of a plurality of first access lines with the third voltage, the first pillar coupled with the first access line.

Aspect 3: The method, apparatus, or non-transitory computer-readable medium of aspect 2, further including operations, features, circuitry, logic, means, or instructions, or any combination thereof for biasing one or more additional access lines of the plurality of first access lines with a fourth voltage, where the fourth voltage is less than the first voltage and greater than the second voltage.

Aspect 4: The method, apparatus, or non-transitory computer-readable medium of any of aspects 2 through 3, where programming the memory cell further includes operations, features, circuitry, logic, means, or instructions, or any combination thereof for biasing a second pillar of the plurality of pillars with the third voltage, the second pillar being coupled with the memory cell.

Aspect 5: The method, apparatus, or non-transitory computer-readable medium of aspect 4, where biasing the second pillar with the third voltage includes operations, features, circuitry, logic, means, or instructions, or any combination thereof for biasing a second access line of the plurality of first access lines with the third voltage, the second pillar coupled with the second access line.

Aspect 6: The method, apparatus, or non-transitory computer-readable medium of any of aspects 4 through 5, where programming the memory cell further includes operations, features, circuitry, logic, means, or instructions, or any combination thereof for activating a first gate line of a plurality of first gate lines located at a first end of the first pillar, where the first gate line is coupled with the first pillar, and where biasing the first pillar and the second pillar of the plurality of pillars is in accordance with activating the first gate line.

Aspect 7: The method, apparatus, or non-transitory computer-readable medium of aspect 6, further including operations, features, circuitry, logic, means, or instructions, or any combination thereof for deactivating one or more other gate lines of the plurality of first gate lines in accordance with activating the first gate line of the plurality of first gate lines.

Aspect 8: The method, apparatus, or non-transitory computer-readable medium of any of aspects 6 through 7, where programming the memory cell further includes operations, features, circuitry, logic, means, or instructions, or any combination thereof for deactivating a second gate line of a plurality of second gate lines located at a second end of the first pillar opposite the first end, where the second gate line is coupled with the first pillar and the second pillar and activating one or more other gate lines of the plurality of second gate lines in accordance with deactivating the second gate line of the plurality of second gate lines.

Aspect 9: The method, apparatus, or non-transitory computer-readable medium of aspect 8, further including operations, features, circuitry, logic, means, or instructions, or any combination thereof for biasing one or more access lines of a plurality of second access lines with a fourth voltage in accordance with activating the one or more other gate lines of the plurality of second gate lines, where the fourth voltage is less than the first voltage and greater than the second voltage, and where the one or more access lines of the plurality of second access lines are coupled with the second gate line.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: A memory device, including: a set of pillars including a first pillar, a second pillar, and a third pillar; a first pier positioned between the first pillar and the second pillar, the first pier including a conductive layer, a plurality of first memory cells coupled with a first portion of the conductive layer at a first end of the first pier, and a plurality of second memory cells coupled with a second portion of the conductive layer at a second end of the first pier; a plurality of pairs of conductive paths each including a first conductive path coupling the conductive layer of the first pier with the first pillar and a second conductive path coupling the conductive layer of the first pier with the second pillar; a plurality of first word lines each coupled with each first memory cell of the plurality of first memory cells of the first pier; a plurality of second word lines each coupled with each second memory cell of the plurality of second memory cells of the first pier; and a second pier positioned between the second pillar and the third pillar and isolating the second pillar from the third pillar.

Aspect 11: The memory device of aspect 10, further including: a set of first access lines positioned at a first end of the set of pillars and extending along a first direction, where each pillar of the set of pillars is coupled with a respective first access line of the set of first access lines, and where each first access line of the set of first access lines is configured to a bias a corresponding pillar of the set of pillars.

Aspect 12: The memory device of aspect 11, further including: a first gate line coupled with each pillar of the set of pillars at the first end and extending along a second direction perpendicular to the first direction, where each pillar of the set of pillars is associated with the respective first access line via the first gate line.

Aspect 13: The memory device of any of aspects 11 through 12, where the first pillar is configured as a drain for accessing a respective first memory cell of the plurality of first memory cells or a respective second memory cell of the plurality of second memory cells in accordance with a first access line of the set of first access lines biasing the first pillar to a first voltage.

Aspect 14: The memory device of aspect 13, where the second pillar is configured as a source for accessing the respective first memory cell of the plurality of first memory cells or the respective second memory cell of the plurality of second memory cells in accordance with a second access line of the set of first access lines biasing the second pillar to the first voltage.

Aspect 15: The memory device of any of aspects 11 through 14, further including: a set of second access lines positioned at a second end of the set of pillars opposite from the first end and extending along the first direction, where each pillar of the set of pillars is coupled with a respective second access line of the set of second access lines, and where each access line of the set of second access lines is configured to bias a respective pillar of the set of pillars.

Aspect 16: The memory device of aspect 15, further including: a second gate line coupled with each pillar of the set of pillars at the second end and extending along a second direction perpendicular to the first direction, where each pillar of the set of pillars is associated with the respective second access line via the second gate line.

Aspect 17: The memory device of any of aspects 10 through 16, where each first conductive path couples a respective first memory cell of the plurality of first memory cells and a respective second memory cell of the plurality of second memory cells with the first pillar, and each second conductive path couples the respective first memory cell of the plurality of first memory cells and the respective second memory cell of the plurality of second memory cells with the second pillar.

Aspect 18: The memory device of any of aspects 10 through 17, where the first pier includes a core dielectric material coupled with an inner surface of the conductive layer.

Aspect 19: The memory device of any of aspects 10 through 18, where the second pier includes a dielectric material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a 3D structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a set of pillars comprising a first pillar, a second pillar, and a third pillar;
a first pier positioned between the first pillar and the second pillar, the first pier comprising a conductive layer, a plurality of first memory cells coupled with a first portion of the conductive layer at a first end of the first pier, and a plurality of second memory cells coupled with a second portion of the conductive layer at a second end of the first pier;
a plurality of pairs of conductive paths each comprising a first conductive path coupling the conductive layer of the first pier with the first pillar and a second conductive path coupling the conductive layer of the first pier with the second pillar;
a plurality of first word lines each coupled with each first memory cell of the plurality of first memory cells of the first pier;
a plurality of second word lines each coupled with each second memory cell of the plurality of second memory cells of the first pier; and
a second pier positioned between the second pillar and the third pillar and isolating the second pillar from the third pillar.

2. The memory device of claim 1, further comprising:
a set of first access lines positioned at a first end of the set of pillars and extending along a first direction, wherein each pillar of the set of pillars is coupled with a respective first access line of the set of first access lines, and wherein each first access line of the set of first access lines is configured to a bias a corresponding pillar of the set of pillars.

3. The memory device of claim 2, further comprising:
a first gate line coupled with each pillar of the set of pillars at the first end and extending along a second direction perpendicular to the first direction, wherein each pillar of the set of pillars is associated with the respective first access line via the first gate line.

4. The memory device of claim 2, wherein the first pillar is configured as a drain for accessing a respective first memory cell of the plurality of first memory cells or a respective second memory cell of the plurality of second memory cells in accordance with a first access line of the set of first access lines biasing the first pillar to a first voltage.

5. The memory device of claim 4, wherein the second pillar is configured as a source for accessing the respective first memory cell of the plurality of first memory cells or the respective second memory cell of the plurality of second memory cells in accordance with a second access line of the set of first access lines biasing the second pillar to the first voltage.

6. The memory device of claim 2, further comprising:
a set of second access lines positioned at a second end of the set of pillars opposite from the first end and extending along the first direction, wherein each pillar of the set of pillars is coupled with a respective second access line of the set of second access lines, and wherein each access line of the set of second access lines is configured to bias a respective pillar of the set of pillars.

7. The memory device of claim 6, further comprising:
a second gate line coupled with each pillar of the set of pillars at the second end and extending along a second direction perpendicular to the first direction, wherein each pillar of the set of pillars is associated with the respective second access line via the second gate line.

8. The memory device of claim 1, wherein each first conductive path couples a respective first memory cell of the plurality of first memory cells and a respective second memory cell of the plurality of second memory cells with the first pillar, and wherein each second conductive path couples the respective first memory cell of the plurality of first memory cells and the respective second memory cell of the plurality of second memory cells with the second pillar.

9. The memory device of claim 1, wherein the first pier comprises a core dielectric material coupled with an inner surface of the conductive layer.

10. The memory device of claim 1, wherein the second pier comprises a dielectric material.

11. A method for operating a memory device, comprising:
programming a memory cell of a memory array, wherein programming the memory cell comprises:
biasing a first word line of a plurality of word lines with a first voltage, wherein the first word line is coupled with the memory cell;
biasing one or more second word lines of the plurality of word lines with a second voltage that is less than the first voltage; and
biasing a first pillar of a plurality of pillars of the memory array with a third voltage that is less than the second voltage, the first pillar being coupled with the memory cell, wherein a charge is stored in the memory cell in accordance with biasing the first word line with the first voltage, biasing the one or more second word lines with the second voltage, and biasing the first pillar with the third voltage.

12. The method of claim 11, wherein biasing the first pillar with the third voltage comprises:
biasing a first access line of a plurality of first access lines with the third voltage, the first pillar coupled with the first access line.

13. The method of claim 12, further comprising:
biasing one or more additional access lines of the plurality of first access lines with a fourth voltage, wherein the fourth voltage is less than the first voltage and greater than the second voltage.

14. The method of claim 12, wherein programming the memory cell further comprises:
biasing a second pillar of the plurality of pillars with the third voltage, the second pillar being coupled with the memory cell.

15. The method of claim 14, wherein biasing the second pillar with the third voltage comprises:
biasing a second access line of the plurality of first access lines with the third voltage, the second pillar coupled with the second access line.

16. The method of claim 14, wherein programming the memory cell further comprises:
activating a first gate line of a plurality of first gate lines located at a first end of the first pillar, wherein the first gate line is coupled with the first pillar, and wherein biasing the first pillar and the second pillar of the plurality of pillars is in accordance with activating the first gate line.

17. The method of claim 16, further comprising:
deactivating one or more other gate lines of the plurality of first gate lines in accordance with activating the first gate line of the plurality of first gate lines.

18. The method of claim 16, wherein programming the memory cell further comprises:
deactivating a second gate line of a plurality of second gate lines located at a second end of the first pillar opposite the first end, wherein the second gate line is coupled with the first pillar and the second pillar; and
activating one or more other gate lines of the plurality of second gate lines in accordance with deactivating the second gate line of the plurality of second gate lines.

19. The method of claim 18, further comprising:
biasing one or more access lines of a plurality of second access lines with a fourth voltage in accordance with activating the one or more other gate lines of the plurality of second gate lines, wherein the fourth voltage is less than the first voltage and greater than the second voltage, and wherein the one or more access lines of the plurality of second access lines are coupled with the second gate line.

20. A memory device, comprising:
one or more memory arrays; and
processing circuitry coupled with the one or more memory arrays and configured to cause the memory device to:
program a memory cell of the one or more memory arrays, wherein, to program the memory cell, the processing circuitry is configured to cause the memory device to:
bias a first word line of a plurality of word lines with a first voltage, wherein the first word line is coupled with the memory cell;
bias one or more second word lines of the plurality of word lines with a second voltage that is less than the first voltage; and
bias a first pillar of a plurality of pillars of the one or more memory arrays with a third voltage that is less than the second voltage, the first pillar being coupled with the memory cell, wherein a charge is stored in the memory cell in accordance with biasing the first word line with the first voltage, biasing the one or more second word lines with the second voltage, and biasing the first pillar with the third voltage.

21. The memory device of claim 20, wherein, to bias the first pillar with the third voltage, the processing circuitry is configured to cause the memory device to:
bias a first access line of a plurality of first access lines with the third voltage, the first pillar coupled with the first access line.

22. The memory device of claim 21, wherein the processing circuitry is configured to cause the memory device to:
bias one or more additional access lines of the plurality of first access lines with a fourth voltage, wherein the fourth voltage is less than the first voltage and greater than the second voltage.

23. The memory device of claim 21, wherein, to program the memory cell, the processing circuitry is configured to cause the memory device to:
bias a second pillar of the plurality of pillars with the third voltage, the second pillar being coupled with the memory cell.
